(19) United States
(12) Patent Application Publication
(10) Pub. No.: US 2005/0087669 A1
(43) Pub. Date: Apr. 28, 2005

(54) Supporting structure for platform in scanner

(76) Inventors: Jen-Shou Tseng, Miao-Li Hsien (TW); Wei-Hsiang Huang, Miaoli (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,390

(22) Filed: Jul. 17, 2003

(30) Foreign Application Priority Data
Aug. 14, 2002 (TW) 91212597

(51) Int. Cl. H05K 5/00

(52) U.S. Cl. 248/694; 361/679

(57) ABSTRACT

A supporting structure for a platform in a scanner is provided. The scanner has a housing and the supporting structure is located on an interior wall of the housing. The supporting structure includes a buffering component that includes a supporting surface and a stress absorbing body. The stress absorbing body is located beneath the supporting surface to share an external stress received by the supporting surface when the platform is subject to an external force.

### CROSS REFERENCE TO RELATED APPLICATIONS

This application claims the priority benefit of Taiwan application serial no. 91212597, filed Aug. 14, 2002.

### BACKGROUND OF INVENTION

1. Field of the Invention

The present invention relates to a supporting structure for a platform in a scanner apparatus. More specifically, the present invention relates to a supporting structure capable of deforming under the application of an external force to protect the platform from damage.

2. Description of the Related Art

Among current consumer electronic equipment, a scanner apparatus has increasingly become popular because of its low price and high performance. In order to satisfy the user's demands, the scanner apparatus has to be slim and compact with high dip and high scanning speed. In the flatbed scanner apparatus known in the prior art, an A4-sized platform is usually mounted in a housing. The platform may be damaged at stress-concentrated points when excessive external forces are exerted on the platform.

FIG. 1A is a cross-sectional view of the assembly of a housing with a platform in a conventional flatbed scanner apparatus. In FIG. 1A, the housing of the flatbed scanner 100 includes an upper housing 104 and a lower housing 102. The platform 110 is attached on inner walls of the upper housing 104 by means of a double-sided adhesive tape. The upper housing 104, provided with the platform 110, is mounted on the lower housing 102 to form an A4-sized scanning window. The platform 110 is a transparent glass or a transparent acrylic resin sheet. In order to prevent the slide and separation of the platform 110, a plurality of block members 112 are provided on the lower housing 102. Each block member 112 is integrally formed on the lower housing 102 to secure the platform 110 on the upper housing 104.

FIG. 1B is a perspective view of the lower housing provided in a conventional scanner apparatus. As shown, each of the block members 112 can be a set of ribs attached on an inner wall of the lower housing 102. However, the block members 112 are not sufficient to effectively absorb external shocks. Therefore, when an external force is applied on the platform 110, the block members 112 can not absorb the shock. As a result, the platform 110 will likely be damaged due to stress concentration in the block members 112.

### SUMMARY OF INVENTION

It is one object of the present invention to provide a supporting structure for a platform in a scanner apparatus to absorb an external force that is exerted on the platform.

It is another object of the present invention to provide a case body having a support element to protect the embedded platform from damages due to stress concentration.

In order to achieve the above and other objectives, a supporting structure for a platform in a scanner apparatus is provided. The supporting structure is mounted on an interior wall of the scanner apparatus and comprises at least one support element. The support element includes a stress absorbing body that has a supporting surface. The platform is placed upon the supporting surface. The stress absorbing body is located beneath the supporting surface to absorb a stress transmitted through the supporting surface by the platform under the application of an external force thereon. The platform is made of a transparent glass or a transparent acrylic resin. The support element supports the platform at its peripheral portion.

According to one preferred embodiment, the stress absorbing body has a beam structure. The external force exerted on the platform is absorbed via the deformation of the different beam portions of the stress absorbing body. A beam structure of the stress absorbing body has, for example, a “Y” or “X” shape.

According to another preferred embodiment, the stress absorbing body has a curved structure to absorb the external force. The stress absorbing body accordingly has, for example, a flattened “C” shape or an “S” shape.

Still according to still another embodiment, the stress absorbing body includes a combination of beam portions with curved portions to absorb the external force. A corresponding shape is, for example, a “5” shape.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principle of the invention.

FIG. 1A is a cross-sectional view of a housing with platform in a conventional scanner.

FIG. 1B is a perspective view of a conventional scanner having the block members.

FIG. 2A and FIG. 2B are cross-sectional views of a supporting structure for supporting a platform in a scanner according to a first embodiment of the present invention.

FIG. 3A and FIG. 3B are cross-sectional views of a supporting structure for a scanner according to a second embodiment of the present invention.

FIG. 4A and FIG. 4B are cross-sectional views of a supporting structure for a scanner according to a third embodiment of the present invention.

FIG. 5 is a cross-sectional view of a supporting structure for a scanner according to a fourth embodiment of the present invention.

FIG. 6 is a cross-sectional view of a supporting structure for a scanner according to a fifth embodiment of the present invention.

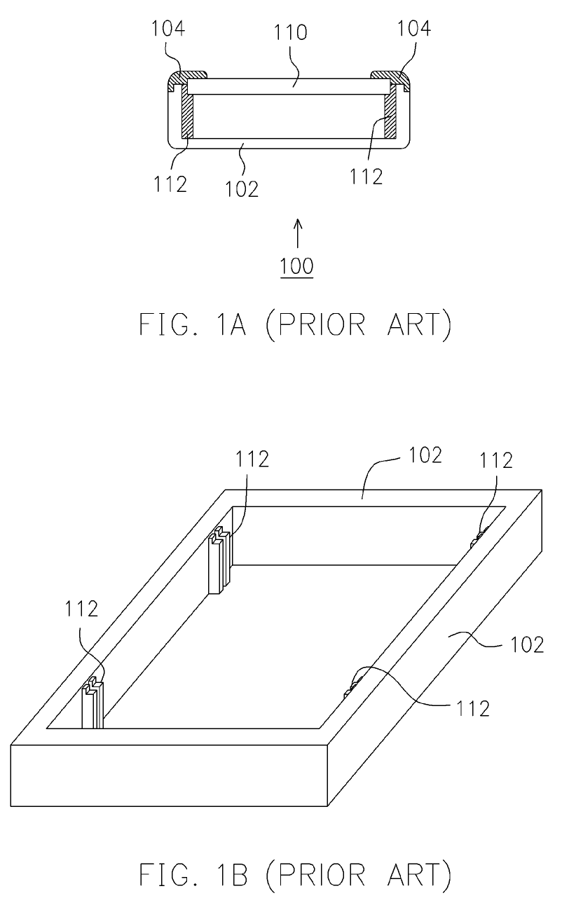

### DETAILED DESCRIPTION

Reference will now be made in detail to the present preferred embodiments of the invention, examples of which are illustrated in the accompanying drawings. Whenever possible, the same reference numbers are used in the drawings and the description to refer to the same or like parts.

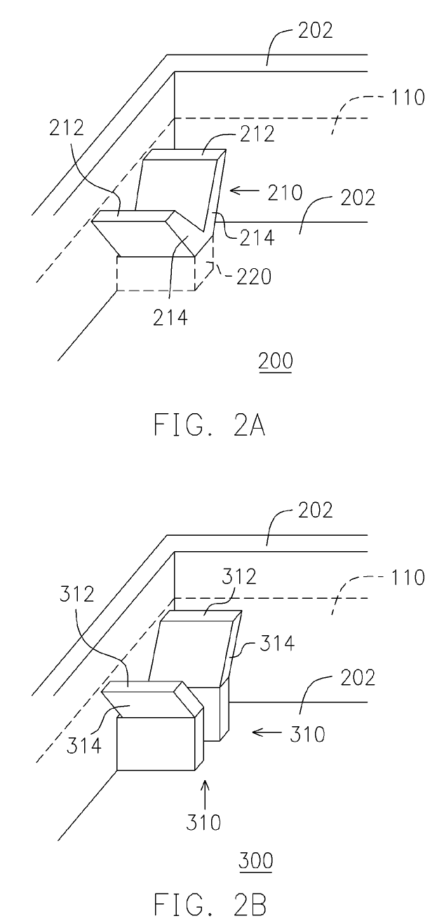

FIG. 2A and FIG. 2B are perspective views of a supporting structure for a platform in a scanner apparatus, especially in a flatbed scanner apparatus, according to a first embodiment of the present invention. In FIG. 2A, a supporting structure 200 includes a plurality of support elements 210, each of which is constructed from a stress absorbing body 214 that includes a supporting surface 212. Each of the support elements 210 is fixedly mounted on an inner wall of a housing of the scanner. The support elements 210 are fixedly attached on the inner wall by, for example, being integrally formed with the housing 202. A stand 220 can be optionally provided on a bottom of the housing to support the stress absorbing body 214. In FIG. 2B, a supporting structure 300 has a pair of symmetric support elements 310 each of which includes a stress absorbing body 314 and a supporting surface 312 thereon. The stress absorbing body 314 is mounted on the inner wall and lies on the bottom of the lower housing.

The platform 110 is securely held on the supporting surfaces 212, 312. The supporting surfaces 212, 312, receiving an external force or shock transmitted from the platform 110, should have a sufficiently large surface area to more uniformly distribute the received stress and prevent consequent damages.

The stress received by the supporting surfaces 212, 312 are absorbed by the stress absorbing bodies 214, 314 beneath the supporting surfaces 212, 312. The stress absorbing bodies 214, 314 are, for example, in a beam shape including beam portions inclined relative to the bottom of the platform 110. The stress absorbing body 214 is formed in, for example, a V-shape, as shown in FIG. 2A. According to a variant example, the stress absorbing body 314 may have a pair of symmetric folded structures as shown in FIG. 2B. Different areas on the stress absorbing bodies 214, 314 are subjected to different amounts of strain to share the external force exerted on the supporting surfaces 200, 300.

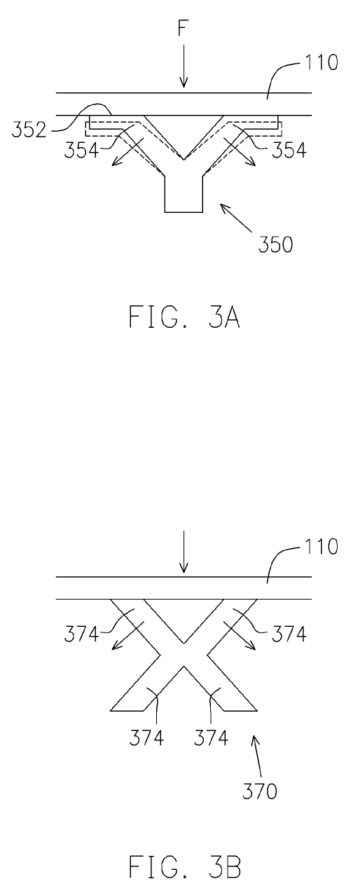

FIG. 3A and FIG. 3B show a supporting structure for a platform in a scanner apparatus according to a second embodiment of the present invention. The broken line shows the deformation of the stress absorbing body 354. The upper end of the stress absorbing body 354 near the supporting surface 352 is subjected to a maximum amount of strain. The amount of strain decreases along the stress absorbing body 354 to its opposite lower end. The stress absorbing body 354 has at least one portion that is inclined related to the platform 110 to share the stress received by the supporting surface 352. The larger the surface area of the supporting surface of the support element, the more stress the supporting surface can tolerate. In this embodiment, the stress absorbing body 354 having two or four inclined portions is illustrated. In FIG. 3A, a support element 350 has symmetric folded stress absorbing bodies 354 constructed according to a Y-shape. In FIG. 3B, a support element 370 has two pairs of symmetric folded stress absorbing bodies 374 constructed according to a X-shape.

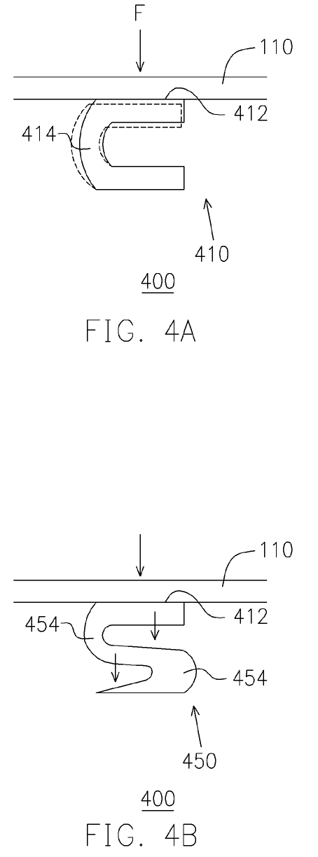

FIG. 4A and FIG. 4B show a supporting structure for a platform in a scanner apparatus according to a third embodiment of the present invention. The supporting structure 400 includes support elements 410 or 450. The support elements 410, 450 respectively include supporting surfaces 412 and stress absorbing bodies 414, 454. The supporting surface 412 has a larger surface area than the supporting surfaces of the above embodiments of the present invention. The stress absorbing bodies 414, 454 have curved structures to share more stress received by the supporting surface 412. Therefore, the platform 110 is protected from damage caused by external shocks.

As shown in FIG. 4A, when the platform 110 is subjected to an external force F, an external side of the curved structure of the stress absorbing body 414 has a larger amount of strain than an interior side thereof. Different areas in the curved structure of the stress absorbing body 414 are subjected to different amounts of strain. The resilient deformation of the curved structure of the stress absorbing body 414, under the application of the external force on the platform, produces a strain distribution in the supporting structure 400 to protect the platform from being damaged.

It is very practical to use the curved structure for stress buffering. In FIG. 4A, the support element 410 has a stress absorbing body 414 formed in a flattened C-shape. In FIG. 4B, the support element 450 has a stress absorbing body 454 formed in a curved S-shape.

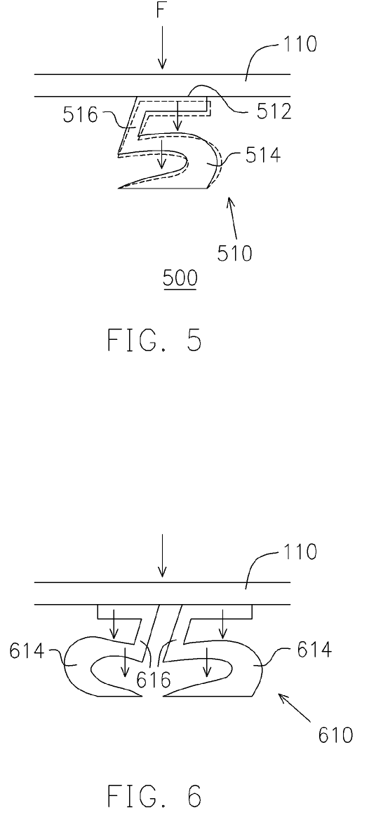

FIG. 5 shows a cross-sectional view of a supporting structure for a platform in a scanner apparatus according to a fourth embodiment of the present invention. The supporting structure 500 includes a support element 510. The support element 510 includes a supporting surface 512 and a stress absorbing body beneath the supporting surface 512. The stress absorbing body includes an inclined beam portion 516 and a curved portion 514. Since the beam portion 516 has a level of deformation different from that of the curved portion 514 under the application of the external force, a combination of the inclined beam portion 516 and the curved portion 514 generates a synergistic effect. Therefore, the stress absorbing body constructed by the inclined beam portion 516 and the curved portion 514 shares more stress received by the supporting surface 512. As illustrated, the stress absorbing body has, for example, a 5-shape.

Another variation of the present invention is shown in FIG. 6. As shown, a supporting structure 600 of FIG. 6 includes a support element 610 having a pair of stress absorbing bodies 614, 616. The stress absorbing bodies 614, 616 respectively have a symmetrical 5-shape.

In view of foregoing, the present invention provides the following advantages over the prior art. The supporting structure of the present invention includes the stress absorbing body that can have one or more beam and/or curved structures. By deformation, the stress absorbing body absorbs the stress received by the supporting surface when the platform, placed on the supporting surface, is subjected to the external force. Therefore, the platform can be protected from damage caused by the external force.

It will be apparent to those skilled in the art that various modifications and variations can be made to the structure of the present invention without departing from the scope or spirit of the invention. In view of the forgoing, it is intended that the present invention cover modifications and variations of this invention provided they fall within the scope of the following claims and their equivalents.

1. A supporting structure for a platform in a scanner, wherein the scanner has a housing and the supporting structure is located on an interior wall of the housing, the supporting structure comprising:
a buffering component comprising:
a supporting surface, wherein the platform is placed upon the supporting surface; and
a stress absorbing body located beneath the supporting surface to share an external stress received by the supporting surface when the platform is subject to an external force.

2. The supporting structure of claim 1, wherein the buffering component is located along a periphery of the platform.

3. The supporting structure of claim 1, wherein the stress absorbing body has an inclined structure.

4. The supporting structure of claim 3, wherein the buffering component has a “Y” shape.

5. The supporting structure of claim 3, wherein the buffering component has an “X” shape.

6. The supporting structure of claim 1, wherein the stress absorbing body has a curved structure.

7. The supporting structure of claim 6, wherein the buffering component has a flattened “C” shape.

8. The supporting structure of claim 6, wherein the buffering component has an “S” shape.

9. The supporting structure of claim 1, wherein the stress absorbing body includes an inclined portion and a curved portion.

10. The supporting structure of claim 9, wherein the buffering component has a “5” shape.

11. The supporting structure of claim 1, wherein platform is made of glass.

12. The supporting structure of claim 1, wherein the platform is made of acrylic resin.

13. A case body for carrying a platform of a scanner, comprising:
a housing having an opening on which the platform is placed; and
a plurality of buffering components mounted on interior walls of the housing, each of the buffering components comprising:
a supporting surface on a top of each buffering component to contact and support the platform; and
a stress absorbing body located beneath the supporting surface to share a stress received by the supporting surface when the platform is subject to an external force.

14. The case body of claim 13, wherein the buffering component is located along a periphery of the platform.

15. The case body of claim 13, wherein the stress absorbing body has an inclined portion.

16. The case body of claim 15, wherein the buffering component has a “Y” shape.

17. The case body of claim 15, wherein the buffering component has a “X” shape.

18. The case body of claim 13, wherein the stress absorbing body has a curved structure.

19. The case body of claim 18, wherein the buffering component has a flattened “C” shape.

20. The case body of claim 18, wherein the buffering component has an “S” shape.

21. The case body of claim 13, wherein the stress absorbing body includes an inclined portion and a curved portion.

22. The case body of claim 21, wherein the buffering component has a “5” shape.

23. The case body of claim 13, wherein the platform is made of glass.

24. The case body of claim 13, wherein the platform is made of acrylic resin.
